(19) United States
(12) Patent Application Publication
(10) Pub. No.: US 2026/0173867 A1
(43) Pub. Date: Jun. 18, 2026

(54) SEMICONDUCTOR MODULE

(71) Applicant: Samsung Electronics Co., Ltd., Suwon-si (KR)

(72) Inventors: Hwanjoo PARK, Suwon-si (KR); BYUNGHAN KO, Suwon-si (KR); Wook MOON, Suwon-si (KR); JINYOUNG CHOI, Suwon-si (KR)

(21) Appl. No.: 19/257,094

(22) Filed: Jul. 1, 2025

(30) Foreign Application Priority Data
Dec. 12, 2024 (KR) 10-2024-0184977

(51) Int. Cl. H01L 23/367; H01L 23/00; H01L 23/053; H01L 23/373; H01L 25/18; H10B 80/00; H10D 80/30

(52) U.S. Cl. CPC H10W 40/228; H10B 80/00; H10D 80/30; H10W 40/258; H10W 76/15; H10W 90/00; H10W 90/288; H10W 90/724; H10W 90/752; H10W 90/754

(57) ABSTRACT

A semiconductor module may include a substrate, a first package mounted on the substrate, a second package mounted on the substrate, a module cover covering the first and second packages, a first indicating portion disposed on a top surface of the module cover and vertically overlapped with the first package, and a second indicating portion disposed on the top surface of the module cover and vertically overlapped with the second package.

### CROSS-REFERENCE TO RELATED APPLICATION(S)

This U.S. non-provisional patent application claims priority under 35 U.S.C. § 119 to Korean Patent Application No. 10-2024-0184977, filed on Dec. 12, 2024, in the Korean Intellectual Property Office, the entire contents of which are hereby incorporated by reference.

### BACKGROUND

With the development of the electronic industry, it becomes possible to cost-effectively manufacture light, small, fast, and high-performance electronic products. A semiconductor package is configured to facilitate the use of a semiconductor chip as a component in an electronic product. Various studies are conducted to improve the reliability of semiconductor packages. In particular, due to the increase in power consumption for higher speeds and larger capacities, thermal characteristics of a semiconductor package and a semiconductor module including the same are of interest.

### SUMMARY

This disclosure provides a semiconductor module with improved heat management system.

Some implementations provide a highly-reliable semiconductor module that is configured to have improved thermal characteristics of a semiconductor package.

According to some implementations, a semiconductor module may include a substrate, a first package mounted on the substrate, a second package mounted on the substrate, a module cover covering the first and second packages, a first indicating portion disposed on a top surface of the module cover and vertically overlapped with the first package, and a second indicating portion disposed on the top surface of the module cover and vertically overlapped with the second package. The first indicating portion may be configured to exchange heat with the first package, and the second indicating portion may be configured to exchange heat with the second package.

According to some implementations, a semiconductor module may include a substrate, a first package and a second package mounted on the substrate and spaced apart from each other in a first direction parallel to a top surface of the substrate, a module cover on the first and second packages, and a first indicating portion and a second indicating portion disposed on the module cover and spaced apart from each other in the first direction. The module cover may include a first recessed portion and a second recessed portion, which are recessed from a top surface of the module cover into the module cover and are spaced apart from each other in the first direction. The first and second indicating portions may be disposed on the first and second recessed portions, respectively. The first indicating portion and the first recessed portion may be vertically overlapped with the first package, and the second indicating portion and the second recessed portion may be vertically overlapped with the second package. The first indicating portion may be configured to exchange heat with the first package, and the second indicating portion may be configured to exchange heat with the second package.

### BRIEF DESCRIPTION OF THE DRAWINGS

FIG. 1 is a plan view illustrating a semiconductor module according to some implementations.

FIG. 2 is a sectional view which is taken along a line A-A′ of FIG. 1 to illustrate a semiconductor module according to some implementations.

FIG. 3 is a sectional view illustrating a first package of FIG. 1.

FIG. 4 is a sectional view illustrating a third package of FIG. 1.

FIG. 5 is a sectional view which is taken along the line A-A′ of FIG. 1 to illustrate a semiconductor module according to some implementations.

FIG. 6 is a sectional view which is taken along the line A-A′ of FIG. 1 to illustrate a semiconductor module according to some implementations.

FIG. 7 is a sectional view which is taken along the line A-A′ of FIG. 1 to illustrate a semiconductor module according to some implementations.

FIG. 8 is a plan view illustrating a semiconductor module according to some implementations.

FIG. 9 is a sectional view which is taken along a line A-A′ of FIG. 8 to illustrate a semiconductor module according to some implementations.

FIG. 10 is a plan view illustrating a semiconductor module according to some implementations.

FIG. 11 is a sectional view which is taken along a line A-A′ of FIG. 10 to illustrate a semiconductor module according to some implementations.

FIG. 12 is a sectional view which is taken along a line B-B′ of FIG. 10 to illustrate a semiconductor module according to some implementations.

### DETAILED DESCRIPTION

Example implementations will now be described more fully with reference to the accompanying drawings, in which example implementations are shown.

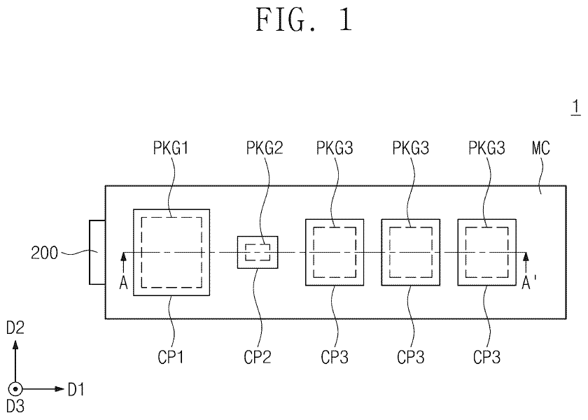

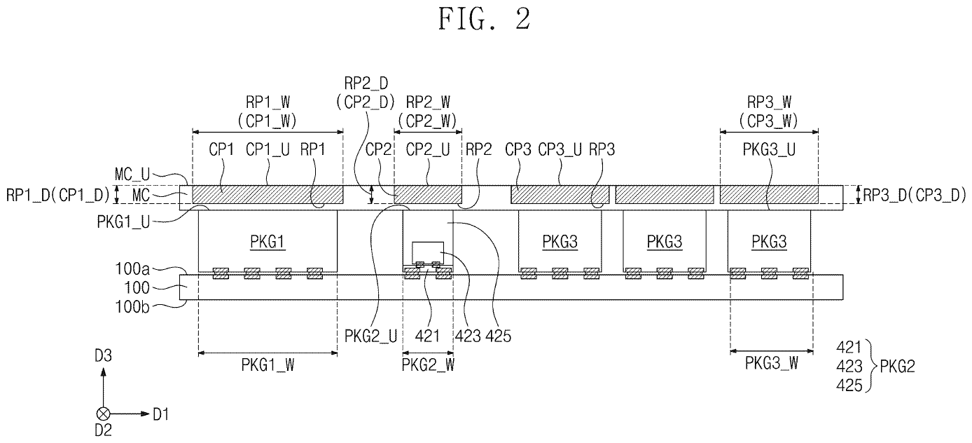

FIG. 1 is a plan view illustrating a semiconductor module according to some implementations. FIG. 2 is a sectional view which is taken along a line A-A′ of FIG. 1 to illustrate a semiconductor module according to some implementations.

Referring to FIGS. 1 and 2, a semiconductor module 1 may include a substrate 100, a first package PKG1, a second package PKG2, a third package PKG3, and a module cover MC covering the first to third packages PKG1, PKG2, and PKG3. The first to third packages PKG1, PKG2, and PKG3 may be spaced apart from each other in a first direction D1.

In the present specification, the first direction D1 may be parallel to a top surface 100a of the substrate 100. A second direction D2 may be parallel to the top surface 100a of the substrate 100 and may not be parallel to the first direction D1. A third direction D3 may be perpendicular to the top surface 100a of the substrate 100.

The semiconductor module 1 may serve as a memory module. The semiconductor module 1 may be a solid state drive (SSD) module, but this disclosure is not limited thereto. The substrate 100 may be a printed circuit board (PCB). The substrate 100 may have a top surface 100a and a bottom surface 100b, which are opposite to each other. A connector 200 may be provided on the top or bottom surface 100a or 100b of the substrate 100. The substrate 100 may be electrically connected to an external device through the connector 200.

The first package PKG1 may be mounted on the top surface 100a of the substrate 100. The first package PKG1 may include a logic chip. The first package PKG1 may serve as a controller package. In some implementations, the first package PKG1 may be configured to write or read data in or from the third package PKG3, based on commands.

In some implementations, a width PKG1_W of the first package PKG1 in the first direction D1 may be larger than a width PKG2_W of the second package PKG2 in the first direction D1 and may be larger than a width PKG3_W of the third package PKG3 in the first direction D1. In addition, during the operation of the semiconductor module 1, heat generated by the first package PKG1 may exceed that generated by the second and third packages PKG2 and PKG3.

The second package PKG2 may be mounted on the substrate 100. The second package PKG2 may be disposed on the top surface 100a of the substrate 100 and may be spaced apart from the first package PKG1 and the third packages PKG3. When viewed in a plan view, the second package PKG2 may be disposed between the first and third packages PKG1 and PKG3. However, the planar arrangement of the second package PKG2 is not limited to this example and may be variously changed. The width PKG3_W of the second package PKG2 in the first direction D1 may be smaller than each of the widths PKG1_W and PKG3_W of the first and third packages PKG1 and PKG3 in the first direction D1.

The second package PKG2 may include a second package substrate 421, a second semiconductor chip 423, and a second mold layer 425. The second semiconductor chip 423 may serve as a buffer memory chip. In some implementations, the second semiconductor chip 423 may be configured to temporarily store data transmitted between the first package PKG1 and the third package PKG3 and/or between the first package PKG1 and the external device. In some implementations, the second semiconductor chip 423 may include a random access memory chip (e.g., a DRAM or SRAM chip). The second package PKG2 may include a plurality of second semiconductor chips 423. The second semiconductor chip 423 is illustrated to be mounted in a flip chip manner, but it may be mounted on the second package PKG2 using bonding wires.

The third package PKG3 may be mounted on the top surface 100a of the substrate 100. When viewed in a plan view, the third package PKG3 may be spaced apart from the first package PKG1 in the first direction D1 and may be spaced apart the second package PKG2 in the first direction D1.

The third package PKG3 may be memory packages including a plurality of memory chips. In some implementations, the memory chips may include inactive memory chips. Each of the memory chips may include one of NAND-type FLASH memory, PRAM, MRAM, ReRAM, FRAM, and/or NOR-type FLASH memory chips. The third package PKG3 may have a large capacity and a high-speed storage ability.

The module cover MC may cover the first, second, and third packages PKG1, PKG2, and PKG3. The module cover MC may be in contact with top surfaces PKG1_U, PKG2_U, and PKG3_U of the first, second, and third packages PKG1, PKG2, and PKG3. The module cover MC may be formed of or include at least one of metallic materials.

A top surface MC_U of the module cover MC may include a first recessed portion RP1, a second recessed portion RP2, and a third recessed portion RP3, which are recessed toward the substrate 100. The first to third recessed portions RP1, RP2, and RP3 may be spaced apart from each other in the first direction D1.

The first recessed portion RP1 may vertically overlap with the first package PKG1. A width RP1_W of the first recessed portion RP1 in the first direction D1 may be equal to or larger than the width PKG1_W of the first package PKG1 in the first direction D1. The width RP1_W of the first recessed portion RP1 in the first direction D1 may be larger than each of widths RP2_W and RP3_W of the second and third recessed portions RP2 and RP3 in the first direction D1. In some implementations, the width RP1_W of the first recessed portion RP1 in the first direction D1 may range from 15 mm to 25 mm. In some implementations, a depth RP1_D of the first recessed portion RP1 (e.g., in the third direction D3) may range from 1 mm to 3 mm. In the case where the depth RP1_D of the first recessed portion RP1 is smaller than 1 mm, heat exchange with the first package PKG1 may not be efficiently achieved. In the case where the depth RP1_D of the first recessed portion RP1 is larger than 3 mm, the mechanical stiffness of the module cover MC and the stability of the semiconductor module may be deteriorated.

The second recessed portion RP2 may vertically overlap with the second package PKG2. A width RP2_W of the second recessed portion RP2 in the first direction D1 may be equal to or larger than the width PKG2_W of the second package PKG2 in the first direction D1. The width RP2_W of the second recessed portion RP2 in the first direction D1 may be smaller than the width RP1_W of the first recessed portion RP1 in the first direction D1. In some implementations, a depth RP2_D of the second recessed portion RP2 (e.g., in the third direction D3) may range from 1 mm to 3 mm. In the case where the depth RP2_D of the second recessed portion RP2 is smaller than 1 mm, heat exchange with the second package PKG2 may not be efficiently achieved. In the case where the depth RP2_D of the second recessed portion RP2 is larger than 3 mm, the mechanical stiffness of the module cover MC and the stability of the semiconductor module may be deteriorated.

The third recessed portion RP3 may vertically overlap with the third package PKG3. A width RP3_W of the third recessed portion RP3 in the first direction D1 may be equal to or larger than a width PRK3_W of the third package PKG3 in the first direction D1. The width RP3_W of the third recessed portion RP3 in the first direction D1 may be smaller than the width RP1_W of the first recessed portion RP1 in the first direction D1 and may be larger than the width RP2_W of the second recessed portion RP2 in the first direction D1. In some implementations, a depth RP3_D of the third recessed portion RP3 (e.g., in the third direction D3) may range from 1 mm to 3 mm. In the case where the depth RP3_D of the third recessed portion RP3 is smaller than 1 mm, heat exchange with the third package PKG3 may not be efficiently achieved. In the case where the depth RP3_D of the third recessed portion RP3 is larger than 3 mm, the mechanical stiffness of the module cover MC and the stability of the semiconductor module may be deteriorated.

Each of a first indicating portion CP1, a second indicating portion CP2, a third indicating portion CP3 may be disposed on the top surface MC_U of the module cover MC. In detail, the first to third indicating portions CP1, CP2, and CP3 may be disposed on the first to third recessed portions RP1, RP2, and RP3, respectively. Each of the first to third indicating portions CP1, CP2, and CP3 may be formed of or include at least one of metallic materials (e.g., copper, platinum, and alloys thereof).

The first to third indicating portions CP1, CP2, and CP3 may have top surfaces CP1_U, CP2_U, and CP3_U that are coplanar with the top surface MC_U of the module cover MC. The top surfaces CP1_U, CP2_U, and CP3_U of the first to third indicating portions CP1, CP2, and CP3 may be visually distinguished from the top surface MC_U of the module cover MC. In detail, each of the top surfaces CP1_U, CP2_U, and CP3_U of the first to third indicating portions CP1, CP2, and CP3 may have a color different from the top surface MC_U of the module cover MC. The top surfaces CP1_U, CP2_U, and CP3_U of the first to third indicating portions CP1, CP2, and CP3 may have a color that is different or distinct from that of the top surface MC_U of the module cover MC. For example, a first color of the top surface CP1_U of the first indicating portion CP1, a second color of the top surface CP2_U of the second indicating portion CP2, and a third color of the top surface CP3_U of the third indicating portion CP3 may be different from a module cover color of the top surface MC_U of the module cover MC. Each of the first to third indicating portions CP1, CP2, and CP3 may further include a white coating layer.

The first indicating portion CP1 may be disposed on the first recessed portion RP1. The first indicating portion CP1 may be vertically overlapped with the first package PKG1. The first indicating portion CP1 may be configured to indicate information on a heat source of the first package PKG1. The first indicating portion CP1 may be configured to exchange heat with the first package PKG1 serving as a heat source, and thus, it may be used to indicate information on a heat source of the first package PKG1.

A planar area of the first indicating portion CP1 may correspond to a planar area of the first package PKG1. A width CP1_W of the first indicating portion CP1 in the first direction D1 may be equal to or larger than the width PKG1_W of the first package PKG1 in the first direction D1. In some implementations, a thickness CP1_D of the first indicating portion CP1 in the third direction D3 may range from 1 mm to 3 mm. Heat generated by the first package PKG1 may exceed that generated by the second or third package PKG2 or PKG3. Thus, during the operation of the semiconductor module, a temperature of the first indicating portion CP1 may be higher than a temperature of each of the second and third indicating portions CP2 and CP3. For example, the first indicating portion CP1 may be configured to have a first temperature. The second indicating portion CP2 may be configured to have a second temperature, and the third indicating portion CP3 may be configured to have a third temperature. The first temperature may greater than the second temperature or/and the third temperature.

The second indicating portion CP2 may be disposed on the second recessed portion RP2. The second indicating portion CP2 may be vertically overlapped with the second package PKG2. The second indicating portion CP2 may be configured to indicate information on a heat source of the second package PKG2. The second indicating portion CP2 may be configured to exchange heat with the second package PKG2 serving as a heat source, and thus, it may be used to indicate information on a heat source of the second package PKG2. A planar area of the second indicating portion CP2 may correspond to a planar area of the second package PKG2. A width CP2_W of the second indicating portion CP2 in the first direction D1 may be equal to or larger than the width PKG2_W of the second package PKG2 in the first direction D1. A thickness CP2_D of the second indicating portion CP2 in the third direction D3 may range from 1 mm to 3 mm.

The third indicating portion CP3 may be disposed on the third recessed portion RP3. The third indicating portion CP3 may be vertically overlapped with the third package PKG3. The third indicating portion CP3 may be configured to indicate information on a heat source of the third package PKG3. The third indicating portion CP3 may be configured to exchange heat with the third package PKG3 serving as a heat source, and thus, it may be used to indicate information on a heat source of the third package PKG3. A planar area of the third indicating portion CP3 may correspond to a planar area of the third package PKG3. A width CP3_W of the third indicating portion CP3 in the first direction D1 may be equal to or larger than the width PKG3_W of the third package PKG3 in the first direction D1. A thickness CP3_D of the third indicating portion CP3 in the third direction D3 may range from 1 mm to 3 mm.

According to some implementations, the module cover MC may include the first to third indicating portions CP1, CP2, and CP3. Each of the indicating portions CP1, CP2, and CP3 may be vertically overlapped with a corresponding one of the packages PKG1, PKG2, and PKG3 and may be configured to exchange heat with the corresponding package. Thus, each of the first to third indicating portions CP1, CP2, and CP3 may be used to indicate information on a heat source of each of the first to third packages PKG1, PKG2, and PKG3. Accordingly, during the operation of the semiconductor module 1, information (such as location, heat generation, and the need for cooling) on the packages PKG1, PKG2, and PKG3 serving as a heat source may be easily identified through the exterior of the semiconductor module 1. A user may be easily obtain information on the heat source through the first to third indicating portions CP1, CP2, and CP3, and this may make it possible to increase the efficiency of the heat management system.

In addition, each of the first to third indicating portions CP1, CP2, and CP3 may be configured to provide information on a heat source of each of the first to third packages PKG1, PKG2, and PKG3 including different semiconductor chips to a user. As an example, the first package PKG1 may include a logic chip, the second package PKG2 may include a volatile memory chip, and the third package PKG3 may include a nonvolatile memory chip. That is, since each of the first to third indicating portions CP1, CP2, and CP3 provides information on a heat source in packages of different kinds to a user, it may be possible to increase the efficiency of the heat management system.

In addition, each of the widths CP1_W, CP2_W, and CP3_W of the indicating portions CP1, CP2, and CP3 in the first direction D1 may be equal to or larger than a corresponding one of the widths PKG1_W, PKG2_W, and PKG3_W of the packages PKG1, PKG2, and PKG3 in the first direction D1. Information on the locations of the packages serving as a heat source may be identified with increased visibility.

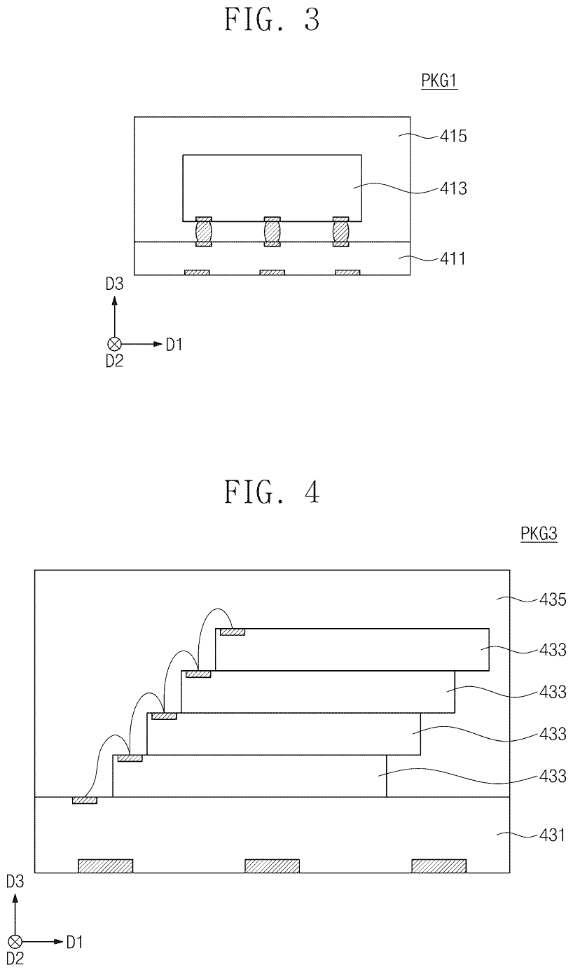

FIG. 3 is a sectional view illustrating a first package of FIG. 1. FIG. 4 is a sectional view illustrating a third package of FIG. 1.

Referring to FIG. 3, the first package PKG1 may include a first package substrate 411, a first semiconductor chip 413, and a first mold layer 415. The first semiconductor chip 413 may be mounted on the first package substrate 411. The first semiconductor chip 413 may include a logic chip, such as, a communication device, a digital signal processor, a controller, or a system-on-chip. The first mold layer 415 may be provided on the first package substrate 411 to cover the first semiconductor chip 413.

Referring to FIG. 4, the third package PKG3 may include a third package substrate 431, third semiconductor chips 433, and a third mold layer 435. The third semiconductor chips 433 may be stacked on the third package substrate 431. The third semiconductor chips 433 may be nonvolatile memory chips. In some implementations, the third semiconductor chips 433 may include NAND-type FLASH memory chips. In other implementations, each of the third semiconductor chips 433 may include one of PRAM, MRAM, ReRAM, FRAM, or NOR FLASH memory chips. The third semiconductor chips 433 may be mounted in a wire bonding manner. The third semiconductor chips 433 may include penetration vias therein and may be mounted in a flip chip manner. The number and arrangement of the third semiconductor chips 433 may be variously modified.

Hereinafter, a method of fabricating a semiconductor module may be described with reference to FIGS. 1 and 2. For concise description, an element previously described with reference to FIGS. 1 to 4 may be identified by the same reference number without repeating an overlapping description thereof.

Referring to FIGS. 1 and 2, the first, second, and third packages PKG1, PKG2, and PKG3 may be mounted on the top surface 100a of the substrate 100. The first to third packages PKG1, PKG2, and PKG3 may be spaced apart from each other in the first direction D1.

The module cover MC may cover the first to third packages PKG1, PKG2, and PKG3. The module cover MC may be in contact with the top surfaces PKG1_U, PKG2_U, and PKG3_U of the first to third packages PKG1, PKG2, and PKG3.

The first recessed portion RP1, the second recessed portion RP2, the third recessed portion RP3 may be formed on the top surface MC_U of the module cover MC. The first to third recessed portions RP1, RP2, and RP3 may be spaced apart from each other in the first direction D1. The first recessed portion RP1 may be formed to vertically overlap with the first package PKG1. The second recessed portion RP2 may be formed to vertically overlap with the second package PKG2. The third recessed portion RP3 may be formed to vertically overlap with the third package PKG3.

In some implementations, the formation of the first to third recessed portions RP1, RP2, and RP3 may include patterning the top surface MC_U of the module cover MC. The patterning process may include, for example, a step of physically patterning the top surface MC_U of the module cover MC or of patterning the top surface MC_U of the module cover MC using a laser beam.

The first, second, and third indicating portions CP1, CP2, and CP3 may be formed on the top surface MC_U of the module cover MC. The first indicating portion CP1 may be formed on the first recessed portion RP1. The second indicating portion CP2 may be formed on the second recessed portion RP2. The third indicating portion CP3 may be formed on the third recessed portion RP3. In some implementations, the formation of the first to third indicating portions CP1, CP2, and CP3 may include depositing a metallic material on a top surface of each of the recessed portions RP1, RP2, and RP3 and performing a planarization process to expose the top surface MC_U of the module cover MC.

According to some implementations, after the formation of the recessed portions RP1, RP2, and RP3 and the indicating portions CP1, CP2, and CP3 on the top surface MC_U of the module cover MC, the module cover MC may be provided to cover the packages PKG1, PKG2, and PKG3. In other words, the recessed portions RP1, RP2, and RP3 and the indicating portions CP1, CP2, and CP3 may be formed on the top surface MC_U of the module cover MC, and then, the module cover MC may be placed to cover the first to third packages PKG1, PKG2, and PKG3.

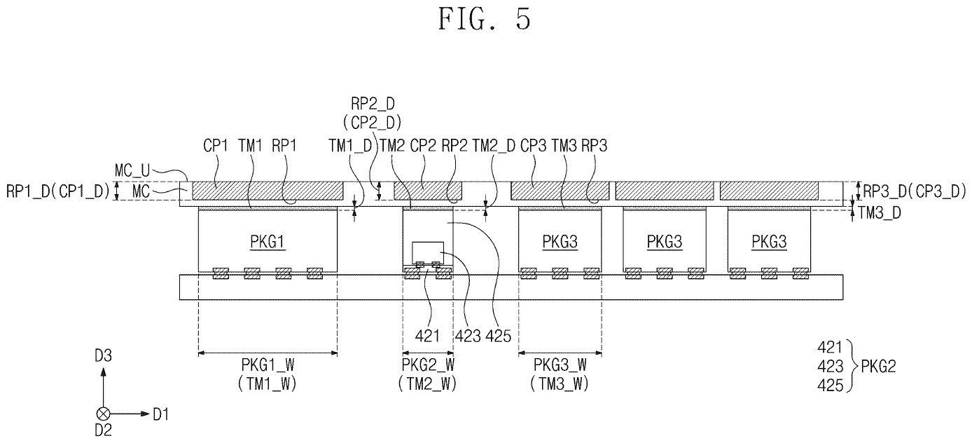

FIG. 5 is a sectional view which is taken along the line A-A′ of FIG. 1 to illustrate a semiconductor module according to some implementations. For concise description, an element previously described with reference to FIGS. 1 to 4 may be identified by the same reference number without repeating an overlapping description thereof.

Referring to FIGS. 1 and 5, the semiconductor module 1 may include the substrate 100, the first package PKG1, the second package PKG2, the third package PKG3, and the module cover MC covering the first to third packages PKG1, PKG2, and PKG3. The first to third packages PKG1, PKG2, and PKG3 may be spaced apart from each other in the first direction D1.

The module cover MC may cover the first, second, and third packages PKG1, PKG2, and PKG3.

The top surface MC_U of the module cover MC may include the first, second, and third recessed portions RP1, RP2, and RP3, which are recessed toward the substrate 100. The first, second, and third recessed portions RP1, RP2, and RP3 may be spaced apart from each other in the first direction D1.

The first to third indicating portions CP1, CP2, and CP3 may be disposed on the first to third recessed portions RP1, RP2, and RP3, respectively. The first indicating portion CP1 may be disposed on the first recessed portion RP1. The first indicating portion CP1 may be vertically overlapped with the first package PKG1. The second indicating portion CP2 may be disposed on the second recessed portion RP2. The second indicating portion CP2 may be vertically overlapped with the second package PKG2. The third indicating portion CP3 may be disposed on the third recessed portion RP3. The third indicating portion CP3 may be vertically overlapped with the third package PKG3.

A first thermally-conductive layer TM1, a second thermally-conductive layer TM2, and a third thermally-conductive layer TM3 may be interposed between the first, second, and third packages PKG1, PKG2, and PKG3 and the module cover MC. Each of the first to third thermally-conductive layers TM1, TM2, and TM3 may include a thermal interface material (TIM). The thermal interface material may be formed of or include a polymer material and thermally-conductive particles.

The first thermally-conductive layer TM1 may be disposed between the first package PKG1 and the module cover MC. A width TM1_W of the first thermally-conductive layer TM1 in the first direction D1 may be equal to the width PKG1_W of the first package PKG1 in the first direction D1. Since a contact area between the first thermally-conductive layer TM1 and the first package PKG1 is large, heat generated by the first package PKG1 may be effectively transferred to the first indicating portion CP1.

The second thermally-conductive layer TM2 may be disposed between the second package PKG2 and the module cover MC. A width TM2_W of the second thermally-conductive layer TM2 in the first direction D1 may be equal to the width PKG2_W of the second package PKG2 in the first direction D1. Since a contact area between the second thermally-conductive layer TM2 and the second package PKG2 is large, heat generated by the second package PKG2 may be effectively transferred to the second indicating portion CP2.

The third thermally-conductive layer TM3 may be disposed between the third package PKG3 and the module cover MC. A width TM3_W of the third thermally-conductive layer TM3 in the first direction D1 may be equal to the width PKG3_W of the third package PKG3 in the first direction D1. Since a contact area between the third thermally-conductive layer TM3 and the third package PKG3 is large, heat generated by the third package PKG3 may be effectively transferred to the third indicating portion CP3.

Each of the first to third thermally-conductive layers TM1, TM2, and TM3 may serve as an adhesive layer. In this case, an adhesion strength between the first to third packages PKG1, PKG2, and PKG3 and the module cover MC may be increased, and the stability of the semiconductor module may be improved.

In addition, each of the thicknesses TM1_D, TM2_D, and TM3_D of the first to third thermally-conductive layers TM1, TM2, and TM3 in the third direction D3 may be smaller than each of the thicknesses CP1_D, CP2_D, and CP3_D of the first to third indicating portions CP1, CP2, and CP3 in the third direction D3. In this case, it may be possible to prevent the size of the semiconductor module 1 from being excessively increased and to increase the efficiency of the heat management system.

Except for the afore-described differences, the semiconductor module according to the present implementations may have substantially the same features as that described with reference to FIGS. 1 to 4.

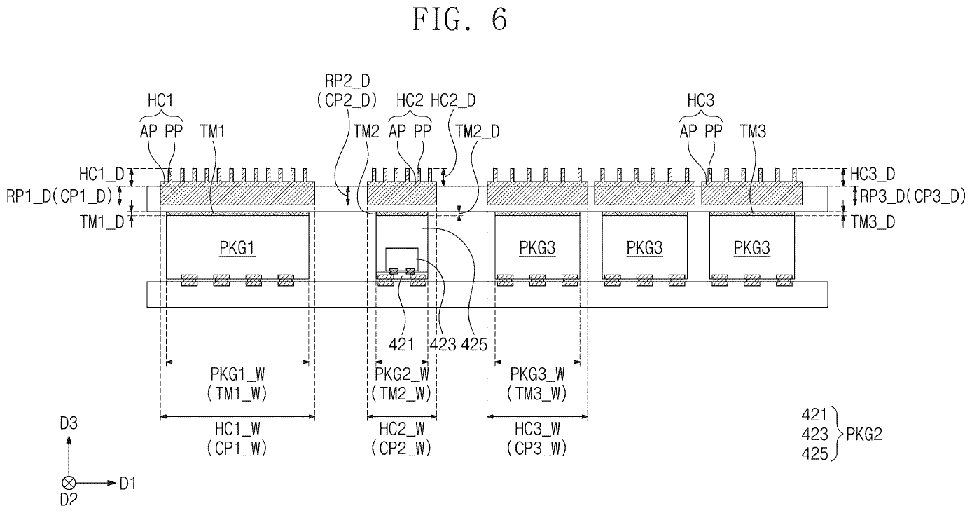

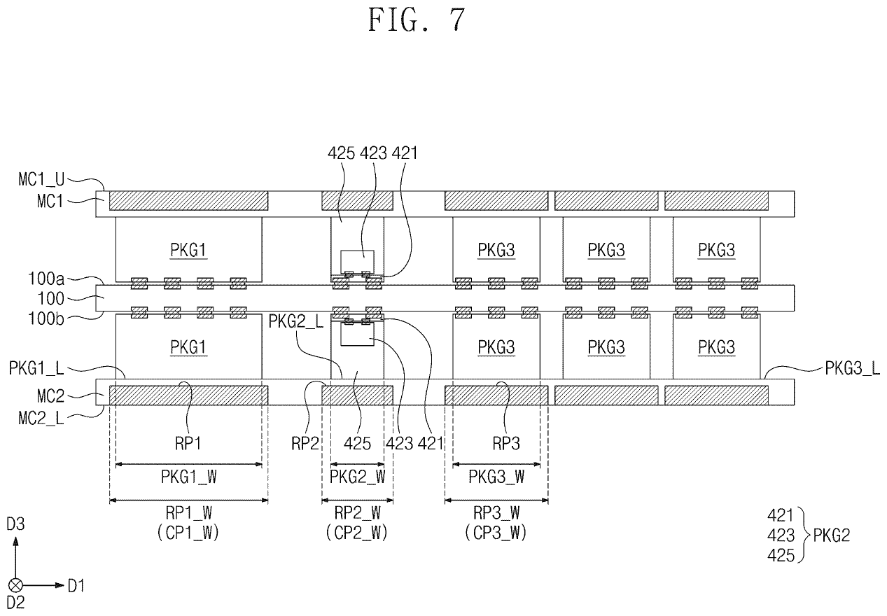

FIG. 6 is a sectional view which is taken along the line A-A′ of FIG. 1 to illustrate a semiconductor module according to some implementations. For concise description, an element previously described with reference to FIGS. 1 to 4 may be identified by the same reference number without repeating an overlapping description thereof.

Referring to FIGS. 1 and 6, the semiconductor module 1 may include the substrate 100, the first package PKG1, the second package PKG2, the third package PKG3, and the module cover MC covering the first to third packages PKG1, PKG2, and PKG3. The first to third packages PKG1, PKG2, and PKG3 may be spaced apart from each other in the first direction D1.

The module cover MC may cover the first, second, and third packages PKG1, PKG2, and PKG3. The module cover MC may be formed of or include at least one of a metallic material.

The top surface MC_U of the module cover MC may include the first, second, and third recessed portions RP1, RP2, and RP3, which are recessed toward the substrate 100. The first, second, and third recessed portions RP1, RP2, and RP3 may be spaced apart from each other in the first direction D1.

The first to third indicating portions CP1, CP2, and CP3 may be disposed on the first to third recessed portions RP1, RP2, and RP3, respectively. The first indicating portion CP1 may be disposed on the first recessed portion RP1. The first indicating portion CP1 may be vertically overlapped with the first package PKG1. The second indicating portion CP2 may be disposed on the second recessed portion RP2. The second indicating portion CP2 may be vertically overlapped with the second package PKG2. The third indicating portion CP3 may be disposed on the third recessed portion RP3. The third indicating portion CP3 may be vertically overlapped with the third package PKG3.

A first heat dissipation portion HC1, a second heat dissipation portion HC2, and a third heat dissipation portion HC3 may be disposed on the first, second, and third indicating portions CP1, CP2, and CP3, respectively.

Each of the first to third heat dissipation portions HC1, HC2, and HC3 may include an adhesion portion AP and a plurality of protruding portions PP, which are extended from a top surface of the adhesion portion AP in the third direction D3. The adhesion portion AP may be in contact with a top surface of each of the first to third indicating portions CP1, CP2, and CP3 and may be physically bonded to each of the first to third indicating portions CP1, CP2, and CP3. Due to the presence of the protruding portions PP, heat generated by the first to third packages PKG1, PKG2, and PKG3 may be easily exhausted through the first to third heat dissipation portions HC1, HC2, and HC3.

In some implementations, each of the first to third heat dissipation portions HC1, HC2, and HC3 may be formed of or include at least one of copper, platinum, and alloys thereof. In some implementations, each of the first to third heat dissipation portions HC1, HC2, and HC3 may be formed of or include the same metallic material as each of the first to third indicating portions CP1, CP2, and CP3. In this case, it may be possible to increase the bonding strength between the first to third heat dissipation portions HC1, HC2, and HC3 and the first to third indicating portions CP1, CP2, and CP3 and to increase the stability of the semiconductor module.

In some implementations, each of lengths HC1_D, HC2_D, and HC3_D of the first to third heat dissipation portions HC1, HC2, and HC3 in the third direction D3 may range from 5 mm to 6 mm. In the case where each of the lengths HC1_D, HC2_D, and HC3_D of the first to third heat dissipation portions HC1, HC2, and HC3 in the third direction D3 is smaller than 5 mm, there may be difficulty in efficiently dissipating heat generated by each of the first to third packages PKG1, PKG2, and PKG3. In the case where each of the lengths HC1_D, HC2_D, and HC3_D of the first to third heat dissipation portions HC1, HC2, and HC3 in the third direction D3 is larger than 6 mm, there may be difficulty in stacking a plurality of semiconductor modules in a highly aligned manner. For example, due to a variation in height of a top surface of each semiconductor module, it may be difficult to align the semiconductor modules to each other.

The first heat dissipation portion HC1 may be disposed on the first indicating portion CP1 and may be vertically overlapped with the first package PKG1. A width HC1_W of the first heat dissipation portion HC1 in the first direction D1 may be equal to the width CP1_W of the first indicating portion CP1 in the first direction D1.

The second heat dissipation portion HC2 may be disposed on the second indicating portion CP2 and may be vertically overlapped with the second package PKG2. A width HC2_W of the second heat dissipation portion HC2 in the first direction D1 may be equal to the width CP2_W of the second indicating portion CP2 in the first direction D1.

The third heat dissipation portion HC3 may be disposed on the third indicating portion CP3 and may be vertically overlapped with the third package PKG3. A width HC3_W of the third heat dissipation portion HC3 in the first direction D1 may be equal to the width CP3_W of the third indicating portion CP3 in the first direction D1.

The first thermally-conductive layer TM1, the second thermally-conductive layer TM2, and the third thermally-conductive layer TM3 may be interposed between the module cover MC and the first, second, and third packages PKG1, PKG2, and PKG3. The first to third thermally-conductive layers TM1, TM2, and TM3 may have top surfaces that are in contact with the module cover MC. Each of the first to third thermally-conductive layers TM1, TM2, and TM3 may be formed of or include a thermal interface material (TIM). The thermal interface material may be formed of or include a polymer material and thermally-conductive particles.

The first thermally-conductive layer TM1 may be disposed between the first package PKG1 and the module cover MC. The width TM1_W of the first thermally-conductive layer TM1 in the first direction D1 may be equal to the width PKG1_W of the first package PKG1 in the first direction D1. Since a contact area between the first thermally-conductive layer TM1 and the first package PKG1 is large, heat generated by the first package PKG1 may be effectively transferred to the first indicating portion CP1.

The second thermally-conductive layer TM2 may be disposed between the second package PKG2 and the module cover MC. The width TM2_W of the second thermally-conductive layer TM2 in the first direction D1 may be equal to the width PKG2_W of the second package PKG2 in the first direction D1. Since a contact area between the second thermally-conductive layer TM2 and the second package PKG2 is large, heat generated by the second package PKG2 may be effectively transferred to the second indicating portion CP2.

The third thermally-conductive layer TM3 may be disposed between the third package PKG3 and the module cover MC. The width TM3_W of the third thermally-conductive layer TM3 in the first direction D1 may be equal to the width PKG3_W of the third package PKG3 in the first direction D1. Since a contact area between the third thermally-conductive layer TM3 and the third package PKG3 is large, heat generated by the third package PKG3 may be effectively transferred to the third indicating portion CP3.

Each of the first to third thermally-conductive layers TM1, TM2, and TM3 may serve as an adhesive layer. In this case, an adhesion strength between the first to third packages PKG1, PKG2, and PKG3 and the module cover MC may be increased, and the stability of the semiconductor module may be improved.

In addition, each of the thicknesses TM1_D, TM2_D, and TM3_D of the first to third thermally-conductive layers TM1, TM2, and TM3 in the third direction D3 may be smaller than each of the thicknesses CP1_D, CP2_D, and CP3_D of the first to third indicating portions CP1, CP2, and CP3 in the third direction D3. In this case, it may be possible to prevent the size of the semiconductor module 1 from being excessively increased and to increase the efficiency of the heat management system.

Except for the afore-described differences, the semiconductor module according to the present implementations may have substantially the same features as that described with reference to FIGS. 1 to 4.

FIG. 7 is a sectional view which is taken along the line A-A′ of FIG. 1 to illustrate a semiconductor module according to some implementations. For concise description, an element previously described with reference to FIGS. 1 to 4 may be identified by the same reference number without repeating an overlapping description thereof.

Referring to FIGS. 1 and 7, the semiconductor module 1 may include the substrate 100, the first packages PKG1, the second packages PKG2, the third packages PKG3, and the module cover MC covering the first to third packages.

The semiconductor module 1 may serve as a memory module. The semiconductor module 1 may be a solid state drive (SSD) module, but this disclosure is not limited thereto. The substrate 100 may be a printed circuit board (PCB). The substrate 100 may have the top surface 100a and the bottom surface 100b, which are opposite to each other. The connector 200 may be provided on the top or bottom surface 100a or 100b of the substrate 100. The substrate 100 may be electrically connected to an external device through the connector 200.

The first packages PKG1 may be disposed on the top and bottom surfaces 100a and 100b of the substrate 100, respectively. The second packages PKG2 may be disposed on the top and bottom surfaces 100a and 100b of the substrate 100, respectively. The third packages PKG3 may be disposed on the top and bottom surfaces 100a and 100b of the substrate 100, respectively.

The first to third packages PKG1, PKG2, and PKG3 on the top surface 100a of the substrate 100 may be vertically overlapped with the first to third packages PKG1, PKG2, and PKG3 on the bottom surface 100b of the substrate 100, but this disclosure is not limited to this example. The disposition or arrangement of the packages on the top surface 100a may be different from that of the packages on the bottom surface 100b.

A first module cover MC1 may cover the first to third packages PKG1, PKG2, and PKG3 on the top surface 100a. The first module cover MC1 may correspond to the module cover MC described with reference to FIGS. 1 to 4.

A second module cover MC2 may cover the first to third packages PKG1, PKG2, and PKG3 on the bottom surface 100b. The second module cover MC2 may have substantially the same structure as the first module cover MC1. In detail, the second module cover MC2 may be in contact with bottom surfaces PKG1_L, PKG2_L, and PKG3_L of the first to third packages PKG1, PKG2, and PKG3 on the bottom surface 100b.

A bottom surface MC2_L of the second module cover MC2 may include the first to third recessed portions RP1, RP2, and RP3, which are recessed toward the substrate 100. Each of the first recessed portions RP1 may be vertically overlapped with one of the first packages PKG1. The width RP1_W of the first recessed portion RP1 in the first direction D1 may be equal to or larger than the width PKG1_W of the first package PKG1 in the first direction D1. Each of the second recessed portions RP2 may be vertically overlapped with the second package PKG2. The width RP2_W of the second recessed portion RP2 in the first direction D1 may be equal to or larger than the width PKG2_W of the second package PKG2 in the first direction D1. Each of the third recessed portions RP3 may be vertically overlapped with the third package PKG3. The width RP3_W of the third recessed portion RP3 in the first direction D1 may be equal to or larger than the width PKG3_W of the third package PKG3 in the first direction D1.

The second module cover MC2 may include the first to third indicating portions CP1, CP2, and CP3. The first to third indicating portions CP1, CP2, and CP3 may be disposed on the first to third recessed portions RP1, RP2, and RP3, respectively. The first indicating portion CP1 may be disposed on the first recessed portion RP1. The first indicating portion CP1 may be vertically overlapped with the first package PKG1 on the bottom surface 100b. The second indicating portion CP2 may be disposed on the second recessed portion RP2. The second indicating portion CP2 may be vertically overlapped with the second package PKG2 on the bottom surface 100b. The third indicating portion CP3 may be disposed on the third recessed portion RP3. The third indicating portion CP3 may be vertically overlapped with the third package PKG3 on the bottom surface 100b.

Except for the afore-described differences, the semiconductor module according to the present implementations may have substantially the same features as that described with reference to FIGS. 1 to 4.

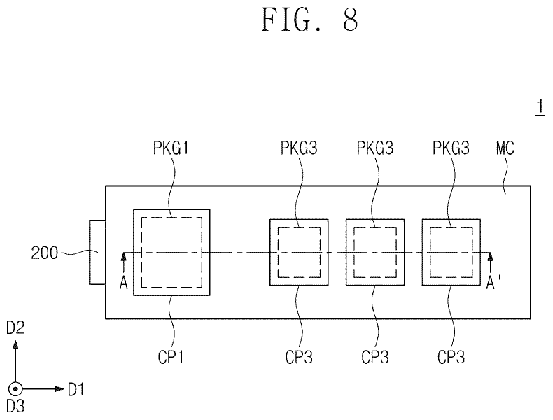

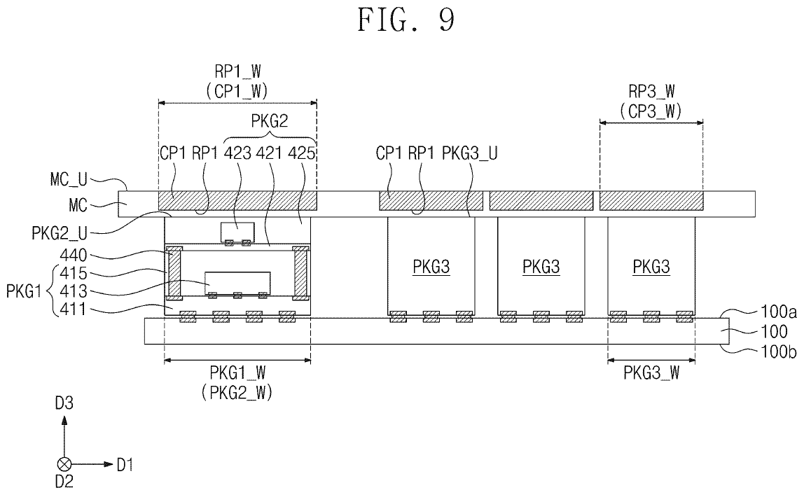

FIG. 8 is a plan view illustrating a semiconductor module according to some implementations. FIG. 9 is a sectional view which is taken along a line A-A′ of FIG. 8 to illustrate a semiconductor module according to some implementations.

Referring to FIGS. 8 and 9, the first package PKG1 may include the first package substrate 411, the first semiconductor chip 413, and the first mold layer 415. The first semiconductor chip 413 may include the logic chip described with reference to FIG. 1. The first package PKG1 may serve as the controller package described with reference to FIGS. 1 to 3.

The second package PKG2 may be stacked on the first package PKG1. In some implementations, the width PKG2_W of the second package PKG2 in the first direction D1 may be equal to the width PKG1_W of the first package PKG1 in the first direction D1.

The second package PKG2 may include the second package substrate 421, the second semiconductor chip 423, and the second mold layer 425. The second semiconductor chip 423 may include a semiconductor chip that is of a kind different from the first semiconductor chip 413. The second semiconductor chip 423 may serve as a buffer memory chip, as described with reference to FIGS. 1 to 4.

A connection terminal 440 may be interposed between the first and second packages PKG1 and PKG2, and in particular, between the first and second package substrates 411 and 421. The connection terminal 440 may be coupled to the first and second packages PKG1 and PKG2. The second package PKG2 may be electrically connected to the first package PKG1 through the connection terminal 440. The second package PKG2 may be stacked on the first package PKG1, and thus, the size of the semiconductor module may be reduced.

The module cover MC may be in contact with the top surfaces PKG2_U and PKG3_U of the second and third packages PKG2 and PKG3. The top surface MC_U of the module cover MC may include the first recessed portion RP1 and the third recessed portion RP3, which are recessed toward the substrate 100.

The first recessed portion RP1 may be vertically overlapped with the first and second packages PKG1 and PKG2. The width RP1_W of the first recessed portion RP1 in the first direction D1 may be equal to or larger than the width PKG1_W of the first package PKG1 in the first direction D1 and the width PKG2_W of the second package PKG2 in the first direction D1. The third recessed portion RP3 may be vertically overlapped with the third package PKG3. The width RP3_W of the third recessed portion RP3 in the first direction D1 may be equal to or larger than the width PKG3_W of the third package PKG3 in the first direction D1. In some implementations, the second recessed portion RP2 may be omitted. Thus, the mechanical stiffness of the module case may be increased.

The first indicating portion CP1 and the third indicating portion CP3 may be disposed on the first recessed portion RP1 and the third recessed portion RP3, respectively. The first indicating portion CP1 may be disposed on the first recessed portion RP1. The first indicating portion CP1 may be vertically overlapped with the first and second packages PKG1 and PKG2. The width CP1_W of the first indicating portion CP1 in the first direction D1 may be equal to or larger than the width PKG1_W of the first package PKG1 in the first direction D1 and the width PKG2_W of the second package PKG2 in the first direction D1.

The third indicating portion CP3 may be disposed on the third recessed portion RP3. The third indicating portion CP3 may be vertically overlapped with the third package PKG3. The width CP3_W of the third indicating portion CP3 in the first direction D1 may be equal to or larger than the width PKG3_W of the third package PKG3 in the first direction D1.

Except for the afore-described differences, the semiconductor module according to the present implementations may have substantially the same features as that described with reference to FIGS. 1 to 4.

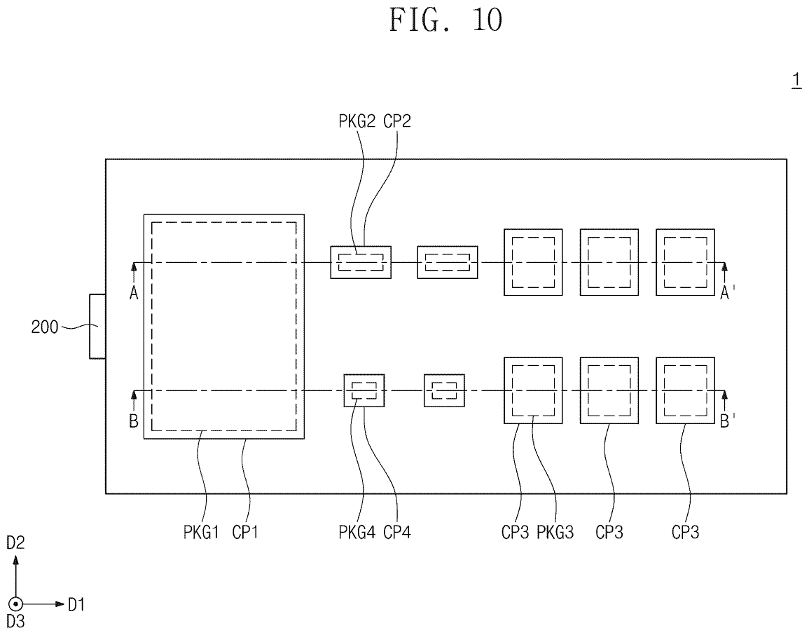

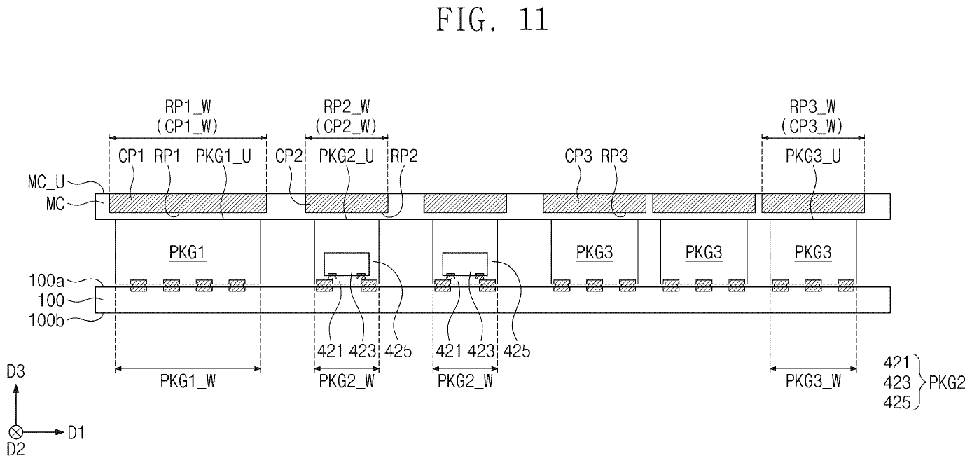

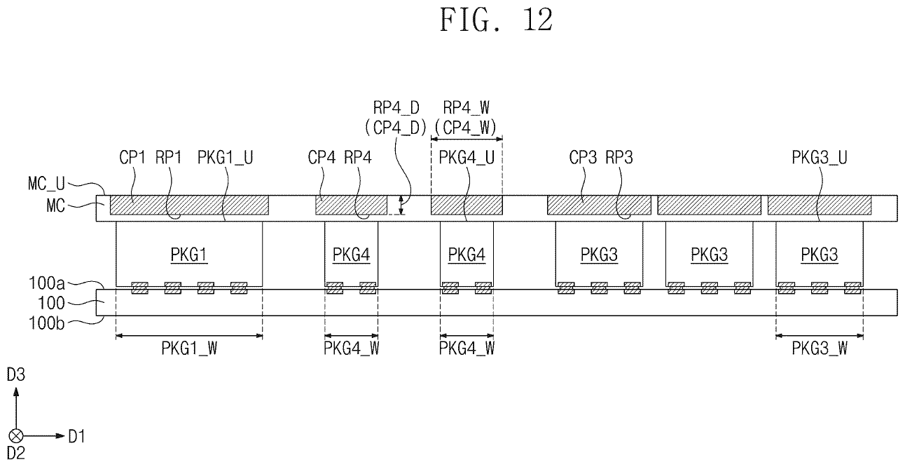

FIG. 10 is a plan view illustrating a semiconductor module according to some implementations. FIGS. 11 and 12 are sectional views illustrating a semiconductor module according to some implementations, FIG. 11 is a sectional view taken along a line A-A′ of FIG. 10, and FIG. 12 is a sectional view taken along a line B-B′ of FIG. 10.

Referring to FIG. 10, a plurality of second packages PKG2 may be provided. The second packages PKG2 may be arranged to form rows parallel to the first direction D1. In some implementations, two or more second packages PKG2 may be provided. A planar arrangement of the second packages PKG2 is not limited to the illustrated example and may be variously changed.

The third packages PKG3 may be arranged to form rows parallel to the first direction D1 and columns parallel to the second direction D2. A planar arrangement of the third packages PKG3 is not limited to a specific arrangement and may be variously changed.

The semiconductor module may further include fourth packages PKG4. The fourth packages PKG4 may include, for example, a power management integrated circuit (PMIC). An electric power may be supplied or controlled to each of the first, second, and third packages PKG1, PKG2, and PKG3 through the fourth packages PKG4.

Referring to FIG. 11, the module cover MC may cover the first, second, and third packages PKG1, PKG2, and PKG3. The module cover MC may be in contact with each of the top surfaces of the first to third packages.

The top surface MC_U of the module cover MC may include the first recessed portion RP1, the second recessed portion RP2, and the third recessed portion RP3, which are recessed toward the substrate 100. The first to third recessed portions RP1 to RP3 may be spaced apart from each other in the first direction D1.

The first recessed portion RP1 may be vertically overlapped with the first package PKG1. The width RP1_W of the first recessed portion RP1 in the first direction D1 may be equal to or larger than the width PKG1_W of the first package PKG1 in the first direction D1. The second recessed portion RP2 may be vertically overlapped with each of the second packages PKG2. The width RP2_W of the second recessed portion RP2 in the first direction D1 may be equal to or larger than the width PKG2_W of each of the second packages PKG2 in the first direction D1. The third recessed portion RP3 may be vertically overlapped with each of the third packages PKG3. The width RP3_W of the third recessed portion RP3 in the first direction D1 may be equal to or larger than the width PKG3_W of each of the third packages PKG3 in the first direction D1.

The first, second, and third indicating portions CP1, CP2, and CP3 may be disposed on the first, second, and third recessed portions RP1, RP2, and RP3, respectively. The first to third indicating portions CP1, CP2, and CP3 may be spaced apart from each other in the first direction D1. The first indicating portion CP1 may be disposed on the first recessed portion RP1. The first indicating portion CP1 may be vertically overlapped with the first package PKG1.

The second indicating portion CP2 may be disposed on the second recessed portion RP2. The second indicating portion CP2 may be vertically overlapped with each of the second packages PKG2. The third indicating portion CP3 may be disposed on the third recessed portion RP3. The third indicating portion CP3 may be vertically overlapped with each of the third packages PKG3.

Referring to FIG. 12, the top surface MC_U of the module cover MC may include the first recessed portion RP1, a fourth recessed portion RP4, and the third recessed portion RP3, which are recessed toward the substrate 100. The first recessed portion RP1, the fourth recessed portion RP4, and the third recessed portion RP3 may be spaced apart from each other in the first direction D1.

The fourth recessed portion RP4 may be vertically overlapped with each of the fourth packages PKG4. A width RP4_W of the fourth recessed portion RP4 in the first direction D1 may be equal to or larger than a width PKG4_W of each of the fourth packages PKG4 in the first direction D1.

In some implementations, a depth RP4_D of the fourth recessed portion RP4 (e.g., in the third direction D3) may range from 1 mm to 3 mm. In the case where the depth RP4_D of the fourth recessed portion RP4 is smaller than 1 mm, heat exchange with the fourth package PKG4 may not be efficiently achieved. In the case where the depth RP4_D of the fourth recessed portion RP4 is larger than 3 mm, the mechanical stiffness of the module cover MC and the stability of the semiconductor module may be deteriorated.

A fourth indicating portion CP4 may be disposed on the fourth recessed portion RP4. The fourth indicating portion CP4 may be vertically overlapped with the fourth package PKG4. The fourth indicating portion CP4 may be configured to indicate information on a heat source of the fourth package PKG4. In some implementations, the fourth indicating portion CP4 may be configured to exchange heat with the fourth package PKG4 serving as a heat source, and thus, it may be used to indicate information on a heat source of the fourth package PKG4. A planar area of the fourth indicating portion CP4 may correspond to a planar area of the fourth package PKG4. A width CP4_W of the fourth indicating portion CP4 in the first direction D1 may be equal to or larger than the width PKG4_W of the fourth package PKG4 in the first direction D1. In some implementations, a thickness CP4_D of the fourth indicating portion CP4 in the third direction D3 may range from 1 mm to 3 mm. The fourth indicating portion CP4 may be formed of or include at least one of metallic materials (e.g., copper, platinum, and alloys thereof).

A top surface CP4_U of the fourth indicating portion CP4 may be coplanar with the top surface MC_U of the module cover MC. The top surface CP4_U of the fourth indicating portion CP4 may have a color that is different or distinct from that of the top surface MC_U of the module cover MC. The fourth indicating portion CP4 may further include a white coating layer.

Except for the afore-described differences, the semiconductor module according to the present implementations may have substantially the same features as that described with reference to FIGS. 1 to 4.

According to some implementations, a semiconductor module may include first to third indicating portions which are vertically overlapped with first to third packages, respectively, which are mounted in a semiconductor module. Owing to the first to third indicating portions, it may be possible to easily obtain information on a heat source of each of the first to third packages. That is, for the semiconductor module according to some implementations, it may be possible to improve efficiency of a heat management system.

In addition, each of the first to third indicating portions may be configured to provide information on a heat source of each of the first to third packages including different semiconductor chips to a user. As an example, the first package may include a logic chip, the second package may include a volatile memory chip, and the third package may include a nonvolatile memory chip. That is, since each of the first to third indicating portions provides information on a heat source in packages of different kinds to a user, it may be possible to increase the efficiency of the heat management system.

Furthermore, a heat dissipation portion may be disposed on the indicating portion. The heat dissipation portion may be used to effectively exhaust heat, which is generated when the semiconductor module is operated. That is, for the semiconductor module according to some implementations, it may be possible to improve thermal and reliability characteristics of a semiconductor package.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations of this disclosure have been particularly shown and described, it will be understood by one of ordinary skill in the art that variations in form and detail may be made therein without departing from the spirit and scope of the attached claims.

What is claimed is:

1. A semiconductor module comprising:
a substrate;
a first package on the substrate;
a second package on the substrate;
a module cover covering the first and second packages;
a first indicating portion on a top surface of the module cover, the first indicating portion being vertically overlapped with the first package; and
a second indicating portion on the top surface of the module cover, the second indicating portion being vertically overlapped with the second package,
wherein the first indicating portion is configured to exchange heat with the first package, and
wherein the second indicating portion is configured to exchange heat with the second package.

2. The semiconductor module of claim 1, wherein the module cover comprises:
a first recessed portion vertically overlapped with the first package and recessed from the top surface of the module cover into the module cover; and
a second recessed portion vertically overlapped with the second package and recessed from the top surface of the module cover into the module cover,
wherein the first indicating portion is on the first recessed portion, and
wherein the second indicating portion is on the second recessed portion.

3. The semiconductor module of claim 2, wherein a depth of each of the first and second recessed portions ranges from 1 mm to 3 mm.

4. The semiconductor module of claim 1, wherein a planar area of the first indicating portion corresponds to a planar area of the first package, and
wherein a planar area of the second indicating portion corresponds to a planar area of the second package.

5. The semiconductor module of claim 1, wherein a width of the first indicating portion in a first direction is larger than or equal to a width of the first package in the first direction,
wherein a width of the second indicating portion in the first direction is larger than or equal to a width of the second package in the first direction, and
wherein the first direction is parallel to a top surface of the substrate.

6. The semiconductor module of claim 5, wherein a width of the first indicating portion in the first direction is larger than a width of the second indicating portion in the first direction.

7. The semiconductor module of claim 1, wherein the first package comprises a logic chip, and
wherein the second package comprises a memory chip.

8. The semiconductor module of claim 1, wherein the first indicating portion is configured to have a first temperature, the second indicating portion is configured to have a second temperature, and the first temperature is greater than the second temperature.

9. The semiconductor module of claim 1, further comprising:
a first heat dissipation portion on the first indicating portion; and
a second heat dissipation portion on the second indicating portion.

10. The semiconductor module of claim 9, wherein a length of each of the first and second heat dissipation portions in a second direction ranges from 5 mm to 6 mm, and
wherein the second direction is perpendicular to a top surface of the substrate.

11. The semiconductor module of claim 9, wherein each of the first and second indicating portions and the first and second heat dissipation portions comprises a metallic material.

12. The semiconductor module of claim 1, wherein a first color of a top surface of the first indicating portion and a second color of a top surface of the second indicating portion are each different from a module cover color of a top surface of the module cover.

13. The semiconductor module of claim 1, comprising thermally-conductive layers interposed between the first package and the module cover and between the second package and the module cover,
wherein a thickness of each of the first and second indicating portions in a second direction is larger than a thickness of each of the thermally-conductive layers in the second direction, and
wherein the second direction is perpendicular to a top surface of the substrate.

14. A semiconductor module comprising:
a substrate;
a first package and a second package on the substrate, the first package and the second package being spaced apart from each other in a first direction parallel to a top surface of the substrate;
a module cover on the first and second packages; and
a first indicating portion and a second indicating portion on the module cover, the first indicating portion and the second indicating portion being spaced apart from each other in the first direction,
wherein the module cover comprises a first recessed portion and a second recessed portion that are recessed from a top surface of the module cover into the module cover and that are spaced apart from each other in the first direction,
wherein the first and second indicating portions are on the first and second recessed portions, respectively,
wherein the first indicating portion and the first recessed portion are vertically overlapped with the first package,
wherein the second indicating portion and the second recessed portion are vertically overlapped with the second package,
wherein the first indicating portion is configured to exchange heat with the first package, and
wherein the second indicating portion is configured to exchange heat with the second package.

15. The semiconductor module of claim 14, comprising:
a first heat dissipation portion on the first indicating portion; and
a second heat dissipation portion on the second indicating portion,
wherein the first indicating portion and the first heat dissipation portion comprise a same metallic material, and
wherein the second indicating portion and the second heat dissipation portion comprise the same metallic material.

16. The semiconductor module of claim 15, wherein each of the first and second heat dissipation portions comprises a plurality of protruding portions protruding in a second direction, and
wherein the second direction is perpendicular to the top surface of the substrate.

17. The semiconductor module of claim 14, comprising a third package disposed between the substrate and the module cover,
wherein the third package comprises a buffer memory chip.

18. The semiconductor module of claim 17, wherein the third package is stacked on the first package.

19. The semiconductor module of claim 14, wherein a width of the first indicating portion in the first direction is equal to or larger than a width of the first package in the first direction, and
wherein a width of the second indicating portion in the first direction is equal to or larger than a width of the second package in the first direction.

20. The semiconductor module of claim 14, wherein a thickness of each of the first and second indicating portions in a second direction is smaller than a largest thickness of the module cover in the second direction, and
wherein the second direction is perpendicular to the top surface of the substrate.
